(19) United States
(12) Patent Application Publication
(10) Pub. No.: US 2026/0293751 A1
(43) Pub. Date: Sep. 24, 2026

(54) IC SENSOR PROCESS UTILIZING GOLD WIRE-BONDING

(71) Applicant: Microchip Technology Inc., Chandler, AZ (US)

(72) Inventors: Patrick McFarland, Gilbert, AZ (US); Arthur B. Eck, Gilbert, AZ (US); Bomy Chen, Newark, CA (US); Steve Nagel, Chandler, AZ (US)

(73) Assignee: Microchip Technology Inc., Chandler, AZ (US)

(21) Appl. No.: 19/197,467

(22) Filed: May 2, 2025

Related U.S. Application Data
(60) Provisional application No. 63/776,731, filed on Mar. 24, 2025.

(51) Int. Cl. H01L 23/00; G01N 27/414; H01L 21/56; H01L 23/31; H01L 23/495

(52) U.S. Cl. CPC H10W 74/124; G01N 27/4141; H10W 74/01; H10W 70/40; H10W 72/075; H10W 72/07504; H10W 90/753; H10W 90/756

(57) ABSTRACT

A semiconductor package comprises a lead frame in the semiconductor package, a chip mounted on the lead frame in the semiconductor package, a sensor in the semiconductor package, a first wire connected to the chip and to the lead frame, and a second wire connected to the sensor and to either the lead frame or the chip. A method comprises providing a lead frame, attaching a chip to the lead frame, wire bonding a first wire to the chip and the lead frame, wire bonding a second wire to either the chip or the lead frame, and depositing a sensor material on the second wire, whereby a sensor is formed.

### RELATED PATENT APPLICATIONS

This application claims priority to commonly owned U.S. Provisional Patent Application No. 63/776,731, filed Mar. 24, 2025, the entire contents of which are hereby incorporated by reference for all purposes.

### TECHNICAL FIELD

The present disclosure relates to semiconductor packages with sensors, in particular, semiconductor packages with sensors connected to lead frames via wire lead bonding.

### BACKGROUND

Environmental monitoring devices typically use a sensor, such as a dopped metal-oxide, to monitor changes in conditions like gases and humidity. Sensors in an integrated package are typically exposed to their environment in order to operate. Being exposed to the environment creates a risk for ionic contamination, especially in adverse environments like oceans and chemical production facilities. Currently used anodes and cathode metals for chip-based sensors also create issues for corrosion and contamination because they are not chemically inert. Additionally, environmental sensors typically have a large footprint and are made by slow and expensive manufacturing processes. A means is desired to make these sensors, while avoiding ionic contamination and doing so in a way that results in a smaller footprint that can be more quickly and cheaply manufactured.

There are several approaches used to create cavities within a packaging area. Typical solutions involve grinding or a gel being deposited that is wet removed later. This exposes the sensitive silicon underneath that can cause environmental contamination and failure over time. Other sensors use a separate package for the sensor material that is then soldered to the AFE/MCU which creates a larger footprint and increased risks for device failure or contamination. The large footprint makes it impractical for certain applications like aerospace or handheld devices, and limits the number of sensing elements that can be placed. This approach also increases sensor noise. Materials other than gold for the sensor metal pads can be used but are expensive and may be produced by expensive equipment for manufacturing.

There is a need for small footprint semiconductor packages with sensors resistant to environmental conditions.

### SUMMARY

According to aspects, there is provided a semiconductor package comprising: a lead frame in the semiconductor package; a chip mounted on the lead frame in the semiconductor package; a first sensor in the semiconductor package; a first wire connected to the chip and to the lead frame; and a second wire connected to the sensor and to either the lead frame or the chip.

Aspects as in the preceding paragraph provide a semiconductor package, wherein the lead frame comprises a first bonding pad, wherein the first wire is connected to the first bonding pad, wherein the lead frame comprises a second bonding pad, wherein the second wire is connected to the second bonding pad.

Aspects as in one of the preceding two paragraphs provide a semiconductor package, comprising a third wire connected to the sensor and to either the lead frame or the chip, wherein the second wire is a cathode of the first sensor and the third wire is an anode of the first sensor.

Aspects as in one of the preceding three paragraphs provide a semiconductor package, comprising: a second sensor; a fourth wire connected to the second sensor and to either the lead frame or the chip; and a fifth wire connected to the second sensor and to either the lead frame or the chip, wherein the fourth wire is a cathode of the second sensor and the fifth wire is an anode of the second sensor.

Aspects as in one of the preceding four paragraphs provide a semiconductor package, wherein the chip is an analog front-end chip or a microcontroller unit chip.

Aspects as in one of the preceding five paragraphs provide a semiconductor package, wherein the first sensor comprises a doped metal oxide sensor to sense a gas selected from: oxygen (O₂), nitrogen (N₂), hydrogen (H₂), carbon dioxide (CO₂), carbon monoxide (CO), hydrocarbon gas, methane (CH₄), nitric oxide (NO), nitrous oxide (N₂O), refrigerant gas (R32 and R454b), water vapor (H₂O), fluorinated gas, sulfur dioxide (SO₂), and ammonia (NH₃).

Aspects as in one of the preceding six paragraphs provide a semiconductor package, comprising a porous ceramic layer over the first sensor.

According to aspects, there is provided a method comprising: providing a lead frame; attaching a chip to the lead frame; wire bonding a first wire to the chip and the lead frame; wire bonding a second wire to either the chip or the lead frame; and depositing a first sensor material on the second wire, whereby a first sensor is formed.

Aspects as in the preceding paragraph provide a method, comprising: depositing a polymer gel on the second wire to form a first mandrel connected to the second wire; encapsulating the lead frame, chip, and first mandrel with an epoxy molding compound; removing a portion of the epoxy molding compound to expose the first mandrel; removing a portion of the first mandrel to form a first cavity in the epoxy molding compound with the second wire in the first cavity, wherein depositing a first sensor material on the second wire comprises depositing the first sensor material in the first cavity; and annealing the first sensor material, whereby a first sensor is formed.

Aspects as in one of the preceding two paragraphs provide a method, wherein wire bonding the first wire comprises wire bonding the first wire to a first bonding pad of the lead frame wherein wire bonding the second wire comprises wire bonding the second wire to a second bonding pad of the lead frame.

Aspects as in one of the preceding three paragraphs provide a method, comprising: wire bonding a third wire to either the lead frame or the chip; depositing the polymer gel on the third wire to form a second mandrel connected to the third wire; and removing a portion of the second mandrel to form a second cavity in the epoxy molding compound with the third wire in the second cavity, wherein the second wire is a cathode and the third wire is an anode.

Aspects as in one of the preceding four paragraphs provide a method, wire bonding a third wire to either the chip or the lead frame; wire bonding a fourth wire to either the chip or the lead frame; wire bonding a fifth wire to either the chip or the lead frame; depositing a polymer gel on the second and third wires to form the first mandrel connected to the second and third wires; depositing the polymer gel on the fourth and fifth wires to form a second mandrel connected to the fourth and fifth wires; encapsulating the lead frame, chip, the first mandrel, and the second mandrel with the epoxy molding compound; removing a first portion of the epoxy molding compound to expose the first mandrel; removing a second portion of the epoxy molding compound to expose the second mandrel; removing a portion of the first mandrel to form a first cavity in the epoxy molding compound with the second and third wires in the first cavity; removing a portion of the second mandrel to form a second cavity in the epoxy molding compound with the fourth and fifth wires in the second cavity; depositing a first sensor material in the first cavity; depositing a second sensor material in the second cavity; annealing the first sensor material, whereby a first sensor is formed; and annealing the second sensor material, whereby a second sensor is formed.

Aspects as in one of the preceding five paragraphs provide a method, wherein depositing a sensor material comprises three-dimensional printing the sensor material.

Aspects as in one of the preceding six paragraphs provide a method, wherein annealing the sensor material comprises laser heating the sensor material.

Aspects as in one of the preceding seven paragraphs provide a method, comprising applying a porous ceramic layer over the sensor.

According to aspects, there is provided a semiconductor sensor package manufactured by a method comprising: providing a lead frame; attaching a chip to the lead frame; wire bonding a first wire to the chip and the lead frame; wire bonding a second wire to either the chip or the lead frame; wire bonding a third wire to either the chip or the lead frame; and depositing a sensor material on the second and third wires, whereby a sensor is formed.

Aspects as in the preceding paragraph provide a semiconductor sensor package manufactured by a method, comprising: depositing a polymer gel on the second and third wires to form a mandrel connected to the second and third wires; encapsulating the lead frame, chip, and mandrel with an epoxy molding compound; removing a portion of the epoxy molding compound to expose the mandrel; removing a portion of the mandrel to form a cavity in the epoxy molding compound with the second and third wires in the cavity, wherein depositing a sensor material on the second and third wires comprises depositing the sensor material in the cavity; and annealing the sensor material, whereby a sensor is formed.

Aspects as in one of the preceding two paragraphs provide a semiconductor sensor package manufactured by a method, wherein depositing a sensor material comprises three-dimensional printing the sensor material wherein annealing the sensor material comprises laser heating the sensor material.

Aspects as in one of the preceding three paragraphs provide a semiconductor sensor package manufactured by a method, wherein the sensor material forms a doped metal oxide sensor to sense a gas selected from: oxygen (O₂), nitrogen (N₂), hydrogen (H₂), carbon dioxide (CO₂), carbon monoxide (CO), hydrocarbon gas, methane (CH₄), nitric oxide (NO), nitrous oxide (N₂O), refrigerant gas (R32 and R454b), water vapor (H₂O), fluorinated gas, sulfur dioxide (SO₂), and ammonia (NH₃).

Aspects as in one of the preceding four paragraphs provide a semiconductor sensor package manufactured by a method, comprising applying a porous ceramic layer over the sensor.

### BRIEF DESCRIPTION OF THE DRAWINGS

A more complete understanding of the disclosure and the advantages thereof may be acquired by referring to the following description, taken in conjunction with the accompanying drawings and wherein:

FIG. 1 shows a cross-sectional, side view of a semiconductor package with a lead frame, an IC chip, and sensors.

FIG. 2A shows a cross-sectional, side view of an IC chip on a lead frame.

FIG. 2B shows a cross-sectional, side view of the chip and lead frame of FIG. 2A.

FIG. 2C shows a cross-sectional, side view of the chip, lead frame, and wires of FIG. 2B.

FIG. 2D shows a cross-sectional, side view of the chip, lead frame, wires, and gel mandrels of FIG. 2C.

FIG. 2E shows a cross-sectional, side view of the chip, lead frame, wires, gel mandrels, and encapsulant of FIG. 2D.

FIG. 2F shows a cross-sectional, side view of the chip, lead frame, wires, and encapsulant of FIG. 2E.

FIG. 2G shows a cross-sectional, side view of the chip, lead frame, wires, cavities, and encapsulant of FIG. 2F.

FIG. 2H shows a cross-sectional, side view of the chip, lead frame, wires, sensors, and encapsulant of FIG. 2G.

FIG. 3A shows a cross-sectional, side view of an IC chip on a lead frame.

FIG. 3B shows a cross-sectional, side view of the chip and lead frame of FIG. 3A.

FIG. 3C shows a cross-sectional, side view of the chip, lead frame, and wires of FIG. 3B.

FIG. 3D shows a cross-sectional, side view of the chip, lead frame, wires, and sensors of FIG. 3C.

FIG. 3E shows a cross-sectional, side view of the chip, lead frame, wires, sensors, and encapsulant of FIG. 3D.

FIG. 4A shows a top view of an IC chip on a lead frame connected by gold wires.

FIG. 4B shows a top view of the IC chip and lead frame of FIG. 4A, wherein doped metal oxide sensors are positioned to intersect the gold wires adjacent the IC chip.

FIG. 5A shows a top view of an IC chip and a jumper chip on a lead frame connected by gold wires.

FIG. 5B shows a top enlarged view of the jumper chip and lead frame of FIG. 5A, wherein sensors are positioned to intersect the gold wires adjacent the jumper chip.

FIG. 6 shows a side view of a doped metal oxide sensor positioned to intersect two gold wires attached to pads of a chip.

FIG. 7A shows a cross-sectional, side view taken at a first cross-section of an IC chip on a lead frame with gold wire connections.

FIG. 7B shows a cross-sectional, side view of the IC chip and the lead frame 702 of FIG. 7A taken at a second cross-section.

FIG. 8 shows a cleaning system to remove debris from a porous cap of a semiconductor package.

The drawings accompanying and forming part of this specification are included to depict certain aspects of the disclosure. The reference number for any illustrated element that appears in multiple different figures has the same meaning across the multiple figures, and the mention or discussion herein of any illustrated element in the context of any particular figure also applies to each other figure, if any, in which that same illustrated element is shown. The features illustrated in the drawings are not necessarily drawn to scale. It should be noted that the features illustrated in the drawings are not necessarily drawn to scale.

### DESCRIPTION

According to aspects, there is provided an inexpensive environmental sensor using doped metal oxides for sensing, cavity packaging and gold wire bonding as the sensor anode and cathode is being proposed. The environmental sensor consists of a number of organic or inorganic sensing elements that are deposited onto a lead frame. The lead frame has separate and dedicated metal bonding pads that are outside of the silicon IC but within the area that will later be packaged. Hollow spaces or cavities are created on the lead frame within the packaging material. These hollow spaces or cavities are made by a 3D printed polymer column or mandrel which is ground down to expose the column or mandrel. The polymer column or mandrel may be dissolved to produce a cavity in the encapsulant. The sensing material may be deposited via 3D printing or ink jet, and the inorganic sensing elements are laser annealed to activate them. An optional process can then be applied after, which involves placing porous resistive ceramic protection. Analog front-ends and MCU on separate chips can also be packaged in the same package, but in a separate area, and then connected via a typical method to the sensor section. The deposited sensor's lead frame pads are then connected with gold wire bonds to the other ICs in the package.

When a lead frame goes through a wire lead bonding process, some of the wire leads may be bonded at respective ends to both a chip and the lead frame. Other of the wire leads may be bonded at one end to the chip and not bonded at the opposite end, so that the wire simply extends in the air up from the chip. A doped metal oxide material may then be deposited over the unbound ends of the wire leads to create a sensor with electrodes (wire leads) attached to the chip.

The doped metal oxide sensor may be created via several processes. One approach is to process using a gel to create a temporary cavity that is later filled with sensor material (an alternative is to create the sensor from sensor material first and then encapsulate in epoxy). After gold wire bonding, the chemical inert cathodes and nodes may be gold (Au), copper redistribution layer (Cu-RDL), or aluminum redistribution layer (Al-RDL).

A three-dimensional printer may deposit doped metal oxide (50~500 um) at the sensor sites to create mandrel polymer that are removed to form cavities. The polymer mandrels may be created using a wet gel. Grinding the epoxy molding compound (EMC) may be used to expose the polymer mandrels. The polymer mandrels may be wet removed with solvent to form cavities. A three-dimensional printer may drop the same paste or different pastes into respective cavities. The epoxy molding compound (EMC) may be ground to expose the paste or pastes in the respective cavities. A laser beam may be used to apply localized heat to anneal-activate the paste or pastes. A pick-place process may position the package to apply a porous resistive ceramic protective layer over the doped metal oxide sensors.

Using metal pads as the bonding site for the sensors helps to keep the sensor area separate from the circuits within the package to protect them from contamination. It also keeps costs much lower as it uses existing technology and processes commonly used in semiconductor manufacturing. It allows for simple gold wire bonding to be used. Because gold wire bonding is an old and well-established process, adapting existing equipment to this new approach will be simpler and more straight forward. Additionally, by using gold as the anode and cathode material, the sensor will be much more chemically inert and resistant to corrosion. The process used allows for a large number of devices to be manufactured at a lower price point, enabling these sensors to be used in devices they might have previously been too expensive for. Using a porous ceramic cover will provide a low cost and easy to manufacture means of keeping the IC sealed and free from potential contamination that the sensor section might be exposed to. By using 3D printing technology, the polymer mandrels can be customized and tuned to specific sensors and also allows for rapid prototyping with minimal cost. Device reliability and longevity could be enhanced by means of this process.

The packaging will consist of separate metal pads areas on the lead frame that will be the bonding sites for the environmental sensors. The sensors sites will have the polymer mandrels created above them so as to open a cavity within the packaging that allows access to the outside world while keeping the rest of packaging area sealed. These metal pads are gold wire bonded to any analog front-ends, MCU or other ICs within the package. Then the 3D printing method is used to manufacture the polymer mandrel. The 3D printing method for manufacturing the polymer mandrel comprises of the printer depositing a polymer onto the silicon that can be wet removed later. A number of placements and sizes can be deposited to allow for the number of sensors designed. The 3D printing process can be changed with a simple software change in most instances for different cavity sizes, shapes, and patterns. Next the IC can be packaged with epoxy as normal. After packaging, the epoxy can be ground to expose the polymer mandrel. The polymer mandrel is then wet removed to form a cavity in the encapsulant. A sensor material is than formed in the cavity to make a sensor that is exposed to the environment. 3D printers can deposit the appropriate paste containing the dopants tuned for specific gases (such as inorganic doped ceramics like tin oxide or organics like PEDOT) into the now exposed cavity. This paste can then either be laser annealed to cure it, or in the case of an organic, can be allowed to dry as the solvent evaporates, depending on the paste material. Once the gas sensor material has cured, if any and as an optional step, a pick and place can place a porous ceramic protective cover over the package to shield from contamination, or another material like a gas permeable polymer membrane.

Aspects provide a solution that uses widely available and inexpensive equipment to manufacture these sensors and their associated ICs to process and transmit data. Because components are contained within one package, the footprint can be greatly reduced and the number of sensing elements can be greatly increased. Gold wire bonding also reduces the risk of sensor failure due to contamination because of its chemical stability and inertness.

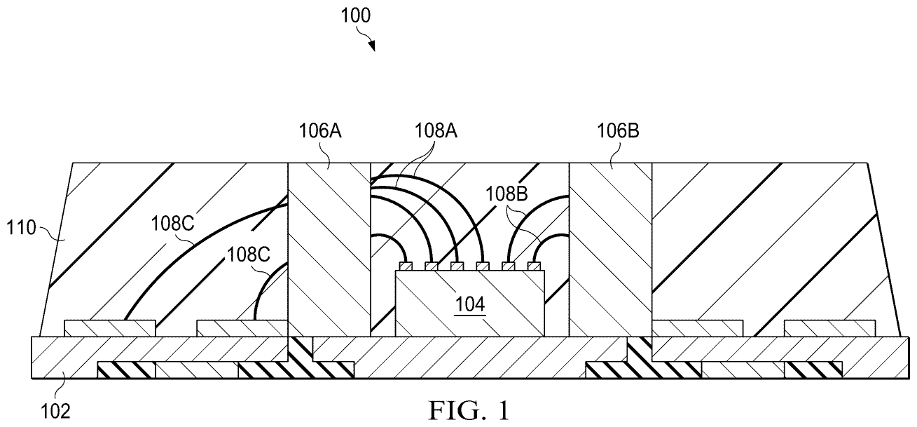

FIG. 1 shows a cross-sectional, side view of a semiconductor package 100 with a lead frame 102, an IC chip 104, and sensors 106A and 106B. The sensors 106A and 106B are connected to the IC chip 104 by wires 108A and 108B, respectively. The IC chip 104 is connected to the lead frame 102 by wires 108C. The sensors 106A and 106B may be doped metal oxide sensors and may be deposited onto the lead frame 102 by a three dimensional printing or ink jet printing process. The sensors 106A and 106B may be positioned on lead frame 102 spaced from the IC chip 104, adjacent the IC chip 104, or above the IC chip 104. Positional separation or spacing may be advantageous, particularly for sensitive chips like analog front-end (AFE) and microcontroller unit (MCU) chips. The semiconductor package 100 may be encapsulated with an encapsulant 110, which may be an epoxy.

A sensor 106 may be formed by depositing a wet metal oxide in a column shape on the lead frame 102 so as to intersect two of the wires 108. The semiconductor package 100 may then be encapsulated with the encapsulant 110. After the encapsulant 100 has hardened or set, then the top end of the column of wet metal oxide may then be exposed via grinding the top layer of encapsulant 110. The exposed wet metal oxide can then be laser annealed to harden. Once hardened, the metal oxide may function as a senser. Other sensor materials can include polymers, enzymes, antigens, in place of metal oxide. The process for alternative materials may vary slightly. For example, polymers and organics may cure in-place without annealing.

The sensors 106A and 106B may be formed by creating a cavity within the encapsulant 110. Prior to encapsulation, a polymer mandrel is positioned on the lead frame, and then the package is encapsulated. This polymer mandrel can then be exposed via grinding the top layer of epoxy encapsulant. The exposed polymer is then dissolved to produce a cavity in the encapsulant. A wet metal oxide can then be squeegeed into the cavity and laser annealed to harden. Once hardened, the metal oxide can begin sensing. Other sensor materials can include polymers, enzymes, antigens, in place of metal oxide. The process for alternative materials may vary slightly. Polymers/organic may not be laser annealed and can cure in-place.

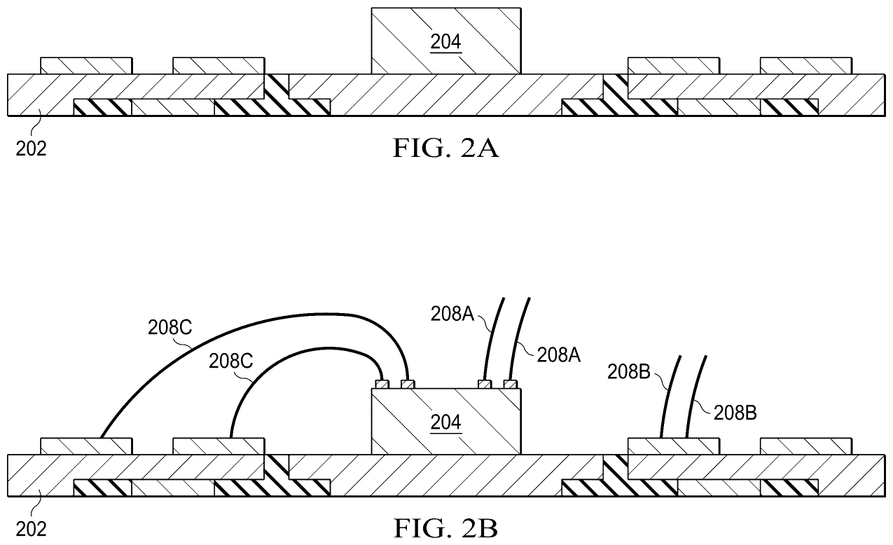

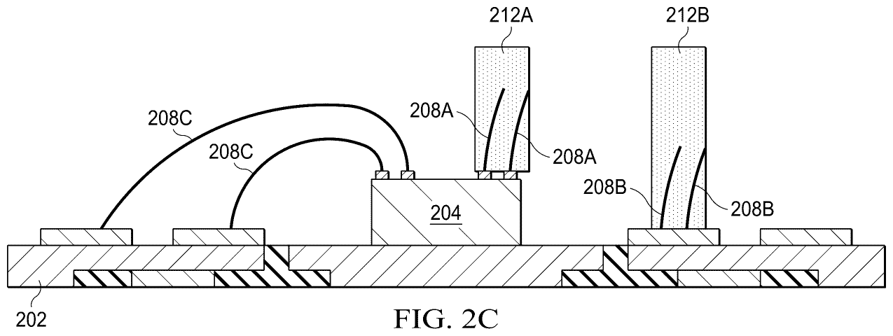

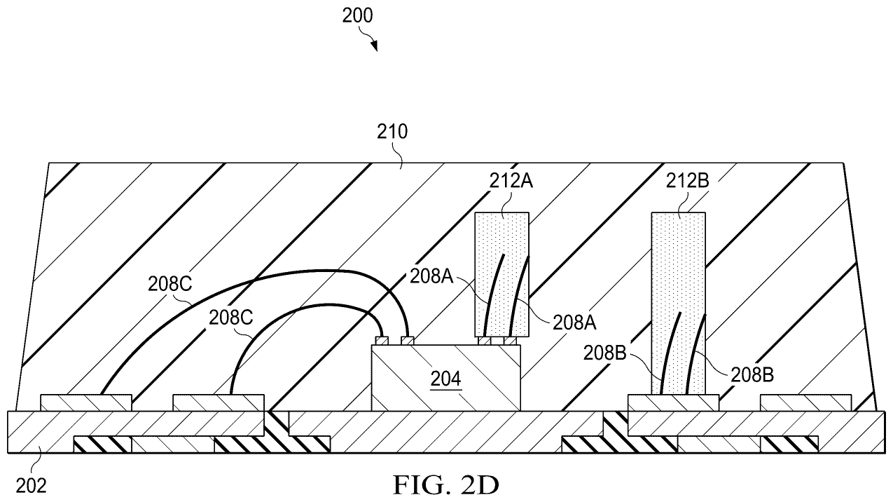

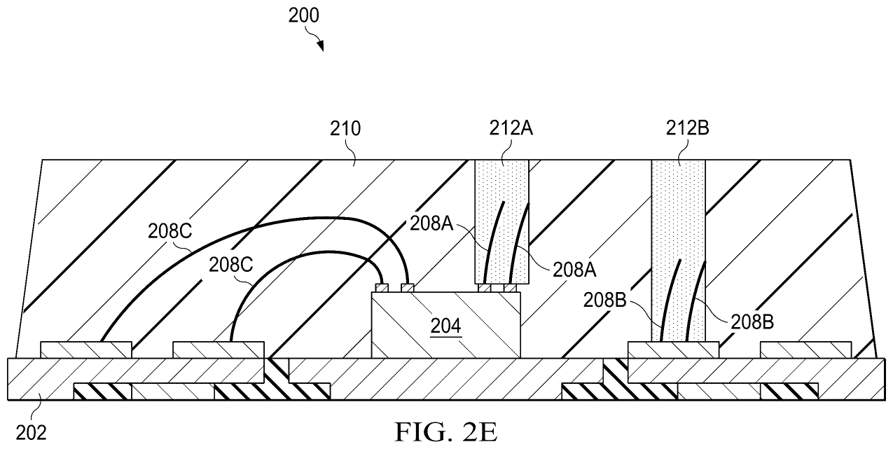

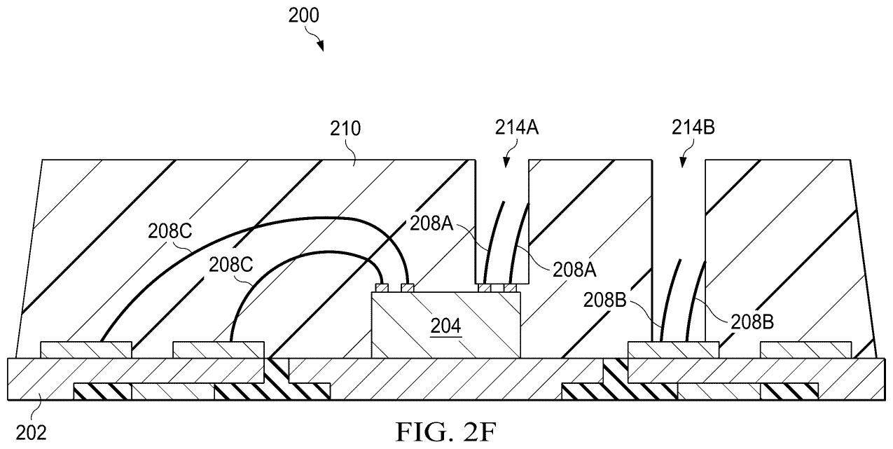

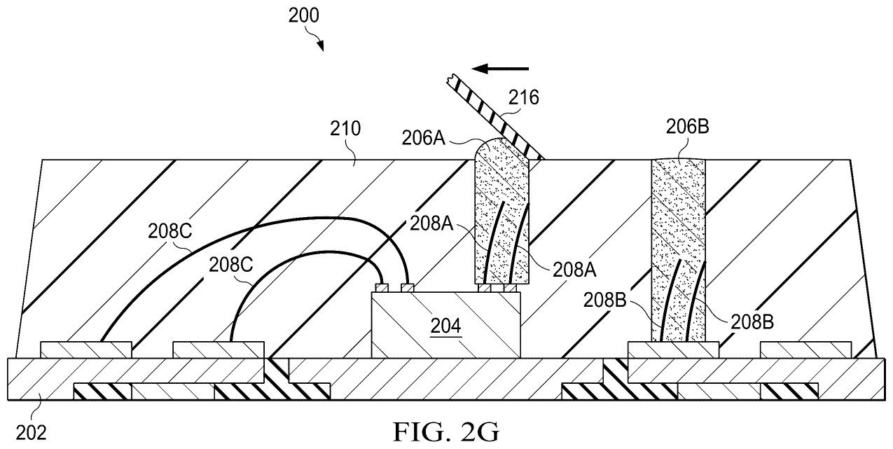

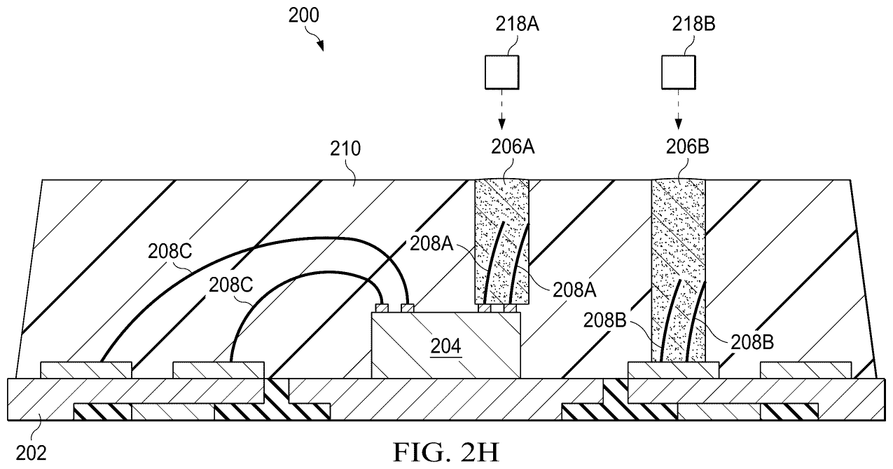

FIGS. 2A-2H show cross-sectional, side views of a semiconductor package during a fabrication process that uses a polymer gel to create cavities in an encapsulant in which sensors are then formed. FIG. 2A shows a cross-sectional, side view of an IC chip 204 on a lead frame 202.

FIG. 2B shows a cross-sectional, side view of the chip 204 and lead frame 202 of FIG. 2A. Wires are wire-bonded to the chip 204 and lead frame 202. In particular, wires 208A are wire-bonded at proximal ends to the chip 204 and the distal ends extend freely without connection to anything. Wires 208B are wire-bonded at proximal ends to the lead frame 202 and the distal ends extend freely without connection to anything. Wires 208C are wire-bonded to the chip 204 and the lead frame 202 to connect the chip 204 to the lead frame 202.

FIG. 2C shows a cross-sectional, side view of the chip 204, lead frame 202, and wires 208 of FIG. 2B. Gel mandrels 112A and 112B are positioned on the chip 204 and lead frame 202 to intersect wires 208A and 208B, respectively. The gel mandrels 112A and 112B may be deposited, jet printed, or 3D printed.

FIG. 2D shows a cross-sectional, side view of the chip 204, lead frame 202, wires 208, and gel mandrels 212 of FIG. 2C. The semiconductor package 200 may then be encapsulated with the encapsulant 210.

FIG. 2E shows a cross-sectional, side view of the chip 204, lead frame 202, wires 208, gel mandrels 212, and encapsulant 210 of FIG. 2D. After the encapsulant 210 has hardened or set, then the top or distal ends of the gel mandrels 212A and 212B may then be exposed by grinding the top layer of encapsulant 210.

FIG. 2F shows a cross-sectional, side view of the chip 204, lead frame 202, wires 208, and encapsulant 210 of FIG. 2E. The gel mandrels 212A and 212B (see FIG. 2E) are dissolved and washed away to produce cavities 214A and 214B in the encapsulant 210 with the wires 208A and 208B in the cavities 214A and 214B, respectively.

FIG. 2G shows a cross-sectional, side view of the chip 204, lead frame 202, wires 208, cavities 214, and encapsulant 210 of FIG. 2F. Wet metal oxide is deposited, injected, or squeegeed into the cavities 214A and 214B (see FIG. 2E) to fabricate sensors 206A and 206B. In FIG. 2G, a squeegee 216 is shown moving in the direction of the arrow to press wet metal oxide into the cavities 214A and 214B (see FIG. 2E). The wet metal oxide is positioned in the cavities to intersect the gold wires 208A and 208B.

FIG. 2H shows a cross-sectional, side view of the chip 204, lead frame 202, wires 208, sensors 206, and encapsulant 210 of FIG. 2G. The exposed wet metal oxide can then be laser annealed to be doped and hardened by lasers 218A and 218B. Once hardened, the metal oxide may function as sensors. Other sensor materials may include polymers, enzymes, antigens, in place of metal oxide. The process for alternative materials may vary slightly. For example, polymers and organics may cure in-place without annealing.

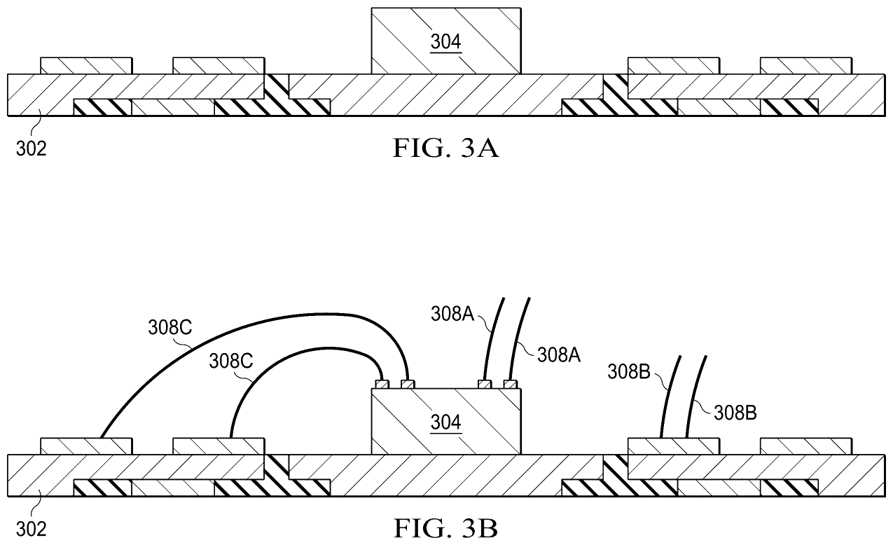

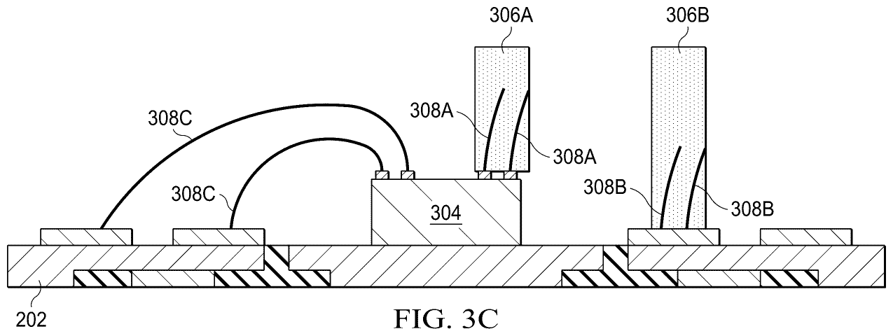

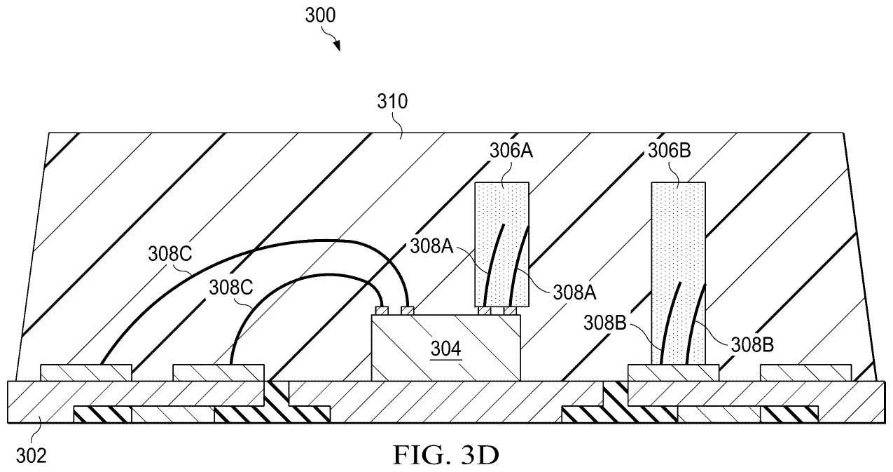

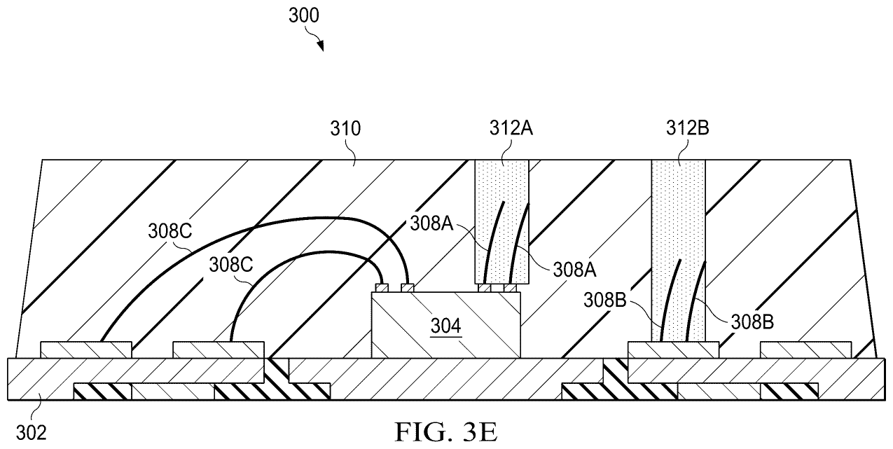

FIGS. 3A-3E show cross-sectional, side views of a semiconductor package during a fabrication process that uses a sensor material to make sensors prior to encapsulating the package. FIG. 3A shows a cross-sectional, side view of an IC chip 304 on a lead frame 302.

FIG. 3B shows a cross-sectional, side view of the chip 304 and lead frame 302 of FIG. 3A. Wires are wire-bonded to the chip 304 and lead frame 302. In particular, wires 308A are wire-bonded at proximal ends to the chip 304 and the distal ends extend freely without connection to anything. Wires 308B are wire-bonded at proximal ends to the lead frame 302 and the distal ends extend freely without connection to anything. Wires 308C are wire-bonded to the chip 304 and the lead frame 302 to connect the chip 304 to the lead frame 302.

FIG. 3C shows a cross-sectional, side view of the chip 304, lead frame 302, and wires 308 of FIG. 3B. A sensor material is positioned on the chip 304 and lead frame 302 to intersect wires 308A and 308B, respectively, to fabricate sensors 306A and 306B. The sensors 306A and 306B may be deposited, jet printed, or 3D printed. The sensor material may comprise polymers, enzymes, antigens, and metal oxide. The process for alternative materials may vary slightly. For example, polymers and organics may cure in-place without annealing.

FIG. 3D shows a cross-sectional, side view of the chip 304, lead frame 302, wires 308, and sensors 306 of FIG. 3C. The semiconductor package 300 may then be encapsulated with the encapsulant 310.

FIG. 3E shows a cross-sectional, side view of the chip 304, lead frame 302, wires 308, sensors 306, and encapsulant 310 of FIG. 3D. After the encapsulant 310 has hardened or set, then the top or distal ends of the sensors 306A and 306B may then be exposed by grinding the top layer of encapsulant 310.

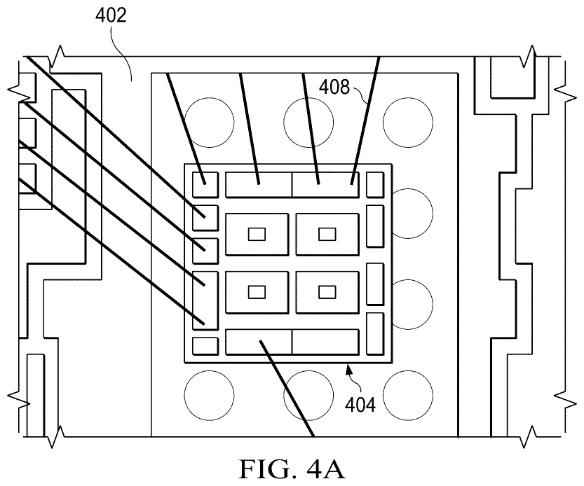

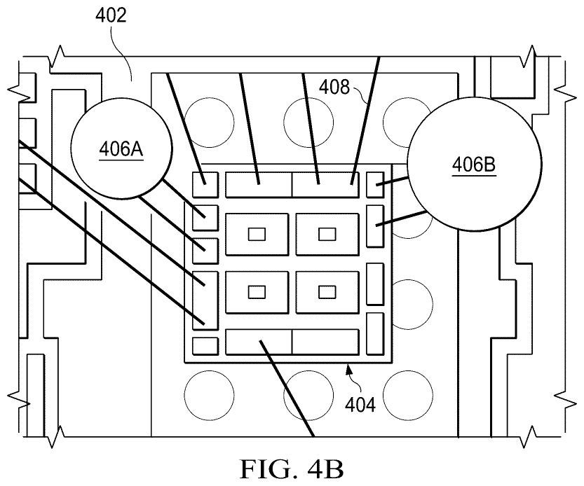

FIG. 4A shows a top view of an IC chip 404 on a lead frame 402 connected by gold wires 408. FIG. 4B shows a top view of the IC chip 404 and lead frame 402 of FIG. 4A, wherein doped metal oxide sensors 406A and 406B are positioned to intersect the gold wires 408 adjacent the IC chip 404. FIG. 4B shows an example of deposit sites for sensor material on the lead frame. In particular, the deposit sites coincide with at least two gold wire leads that are not bound to the lead frame. The two gold wire leads extend from proximal ends attached to pads on the chip and the distal ends of the gold wire leads are not attached to anything. The deposit sites for sensor material on the lead frame may intersect the distal ends of the two gold wire leads.

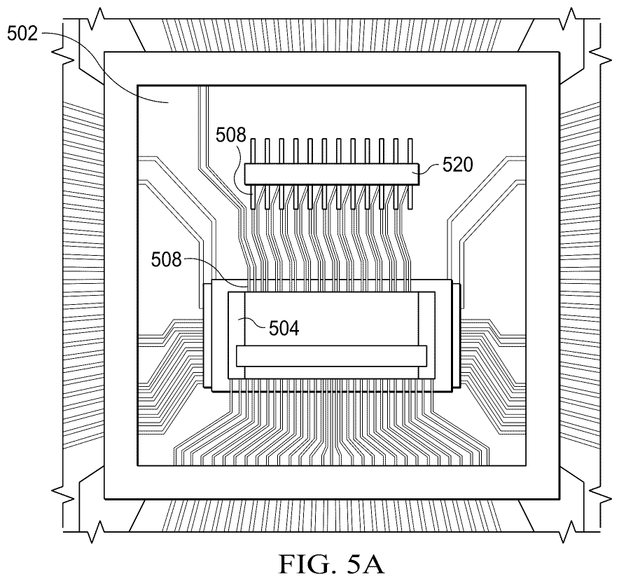

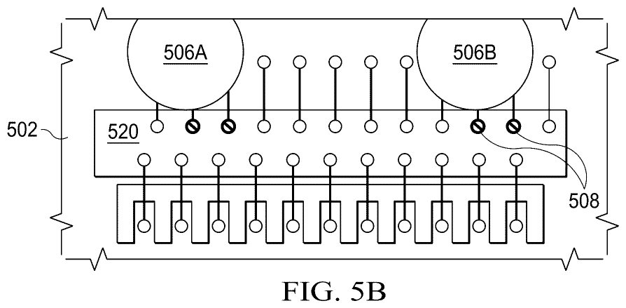

FIG. 5A shows a top view of an IC chip 504 and a jumper chip 520 on a lead frame 502 connected by gold wires 508. FIG. 5B shows a top enlarged view of the jumper chip 520 and lead frame 502 of FIG. 5A, wherein sensors 506A and 506B are positioned to intersect the gold wires 508 adjacent the jumper chip 520. Because the jumper chip 520 is spaced from the IC chip 504, the sensors 506A and 506B may be positioned a distance from the IC chip 504 and still be contained within the semiconductor package 500.

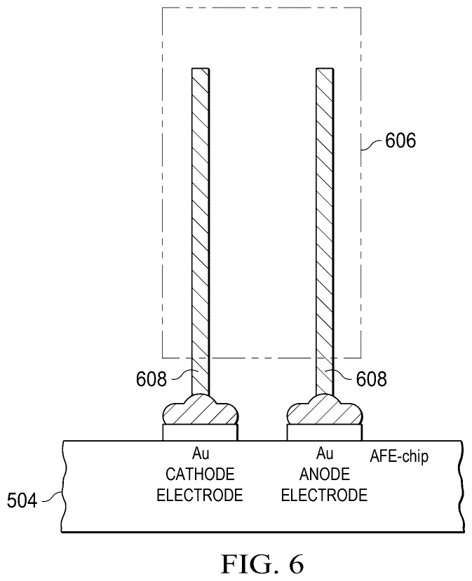

FIG. 6 shows a side view of a doped metal oxide sensor 606 positioned to intersect two gold wires 608 attached to pads of a chip (not shown). The bonded gold wires 608 can be used as the sensor anode and cathode. Many of these can easily and cheaply be placed to increase surface area for the anode and the cathode. Any number of wires may serve as an electrode (anode or cathode) for a sensor. The gold wires 608 are drawn straight up vertically by the machine instead of arched from the chip to the lead frame. Gold is inert compared to other metals and therefore advantageous for sensors exposed to the environment. Gold may be an advantageous choice for sensor electrodes because it is widely used for wire bonding by well-established processes. Lead frames may be lengthened to accommodate a greater number of wire bonds for a given surface area. These lead frames can then be connected to host IC(s).

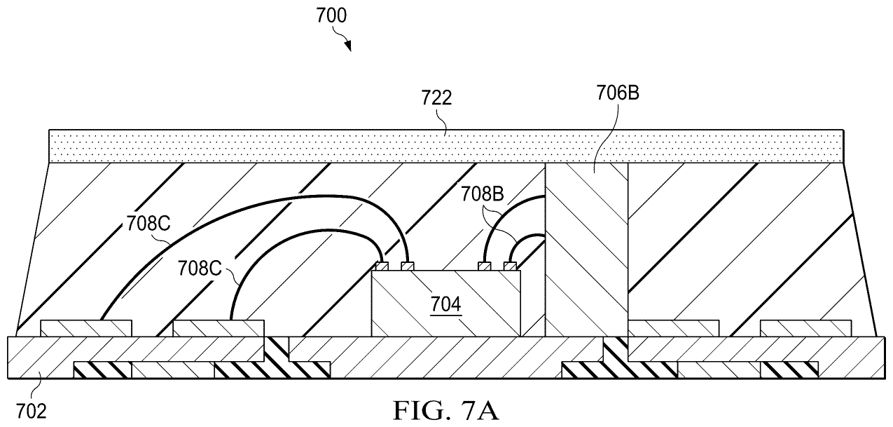

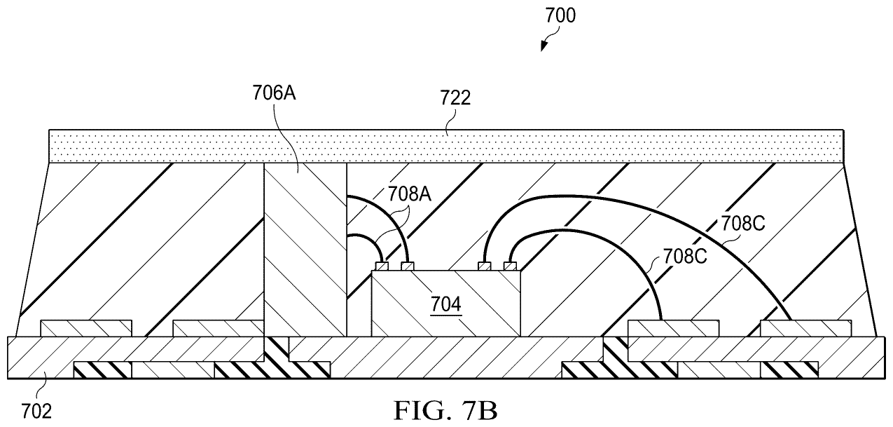

FIG. 7A shows a cross-sectional, side view taken at a first cross-section of an IC chip 704 on a lead frame 702 with gold wire connections. FIG. 7B shows a cross-sectional, side view of the IC chip 704 and the lead frame 702 of FIG. 7A taken at a second cross-section. Two doped metal oxide sensors 706A and 706B are connected to the IC chip 704 by gold wires 708A and 708B, respectively, one to detect gas A and another to detect gas B. In alternative examples, many dopants and sensor materials can be used, depending on design criteria. Additionally, in alternative examples, multiple integrated circuit chips can be placed and wire bonded together on single lead frames, such as AFE and MCU, and still be positioned separately from the sensor on the lead frame. As shown in FIGS. 7A and 7B, a porous cap 722 can be placed on the top of the semiconductor package 700 to seal out contaminants like dust and liquid. This porous cap 722, which may be made of materials like ceramic or polymer, may become plugged or clogged with debris over time. A plugged or clogged porous cap 722 may reduce sensor effectiveness as the porous cap 722 become less penetrable.

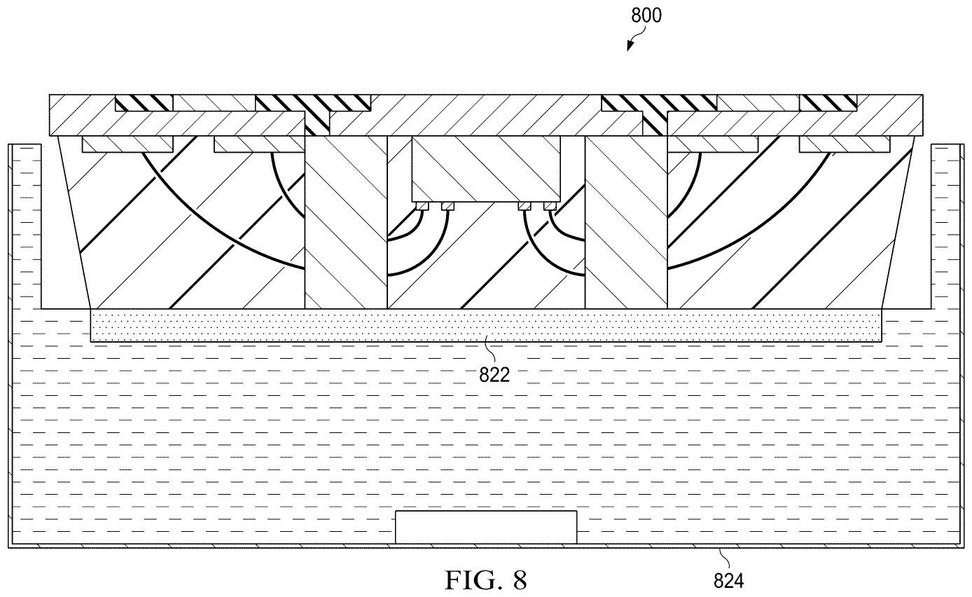

FIG. 8 shows a cleaning system to remove debris from a porous cap 822 of a semiconductor package 800. The cleaning system can be used to clean and regenerate the sensor's porous cap 822, depending on the material and the debris. For example, if the sensor uses an enzyme for detection, the cleaning system can prepare/regenerate the enzyme in the sensor. A wet cleaning tank 824 may heat or agitate the sensor using ultrasound, along with a solvent like deionized water or other depending on sensor materials. Sensors can also have a piezo transducer attached that can be driven at times to clean it. In the case of sensors being fixed to autonomous robots, like robot dogs, the dogs can automatically return to a base station for recharging and sensor cleaning/regenerating. The autonomous vehicles, like dogs and drones, could be used to patrol oil fields, chemical plants, mines, farms, and homes, without limitation, to screen for toxic gases, spills, fires, and smoke, without limitation. Automated cleaning reduces human interaction in hazardous environments and improves safety and performance. The autonomous vehicles, like dogs and drones, may be remote controlled by a human from a safe place.

Sensors disclosed herein may detect or sense oxygen (O₂), nitrogen (N₂), hydrogen (H₂), carbon dioxide (CO₂), carbon monoxide (CO), hydrocarbon gas, methane (CH₄), nitric oxide (NO), nitrous oxide (N₂O), refrigerant gas (R32 and R454b), water vapor (H₂O), fluorinated gases, sulfur dioxide (SO₂), ammonia (NH₃), without limitation.

Although examples have been described above, other variations and examples may be made from this disclosure without departing from the spirit and scope of these disclosed examples.

What is claimed is:

1. A semiconductor package comprising:
a lead frame in the semiconductor package;
a chip mounted on the lead frame in the semiconductor package;
a first sensor in the semiconductor package;
a first wire connected to the chip and to the lead frame; and
a second wire connected to the sensor and to either the lead frame or the chip.

2. The semiconductor package as in claim 1, wherein the lead frame comprises a first bonding pad, wherein the first wire is connected to the first bonding pad, wherein the lead frame comprises a second bonding pad, wherein the second wire is connected to the second bonding pad.

3. The semiconductor package as in claim 1, comprising a third wire connected to the sensor and to either the lead frame or the chip, wherein the second wire is a cathode of the first sensor and the third wire is an anode of the first sensor.

4. The semiconductor package as in claim 1, comprising:
a second sensor;
a fourth wire connected to the second sensor and to either the lead frame or the chip; and
a fifth wire connected to the second sensor and to either the lead frame or the chip, wherein the fourth wire is a cathode of the second sensor and the fifth wire is an anode of the second sensor.

5. The semiconductor package as in claim 1, wherein the chip is an analog front-end chip or a microcontroller unit chip.

6. The semiconductor package as in claim 1, wherein the first sensor comprises a doped metal oxide sensor to sense a gas selected from: oxygen (O₂), nitrogen (N₂), hydrogen (H₂), carbon dioxide (CO₂), carbon monoxide (CO), hydrocarbon gas, methane (CH₄), nitric oxide (NO), nitrous oxide (N₂O), refrigerant gas (R32 and R454b), water vapor (H₂O), fluorinated gas, sulfur dioxide (SO₂), and ammonia (NH₃).

7. The semiconductor package as in claim 1, comprising a porous ceramic layer over the first sensor.

8. A method comprising:
providing a lead frame;
attaching a chip to the lead frame;
wire bonding a first wire to the chip and the lead frame;
wire bonding a second wire to either the chip or the lead frame; and
depositing a first sensor material on the second wire, whereby a first sensor is formed.

9. The method as in claim 8, comprising:
depositing a polymer gel on the second wire to form a first mandrel connected to the second wire;
encapsulating the lead frame, chip, and first mandrel with an epoxy molding compound;
removing a portion of the epoxy molding compound to expose the first mandrel;
removing a portion of the first mandrel to form a first cavity in the epoxy molding compound with the second wire in the first cavity, wherein depositing a first sensor material on the second wire comprises depositing the first sensor material in the first cavity; and
annealing the first sensor material, whereby a first sensor is formed.

10. The method as in claim 8, wherein wire bonding the first wire comprises wire bonding the first wire to a first bonding pad of the lead frame wherein wire bonding the second wire comprises wire bonding the second wire to a second bonding pad of the lead frame.

11. The method as in claim 8, comprising:
wire bonding a third wire to either the lead frame or the chip;
depositing a polymer gel on the third wire to form a second mandrel connected to the third wire; and
removing a portion of the second mandrel to form a second cavity in an epoxy molding compound with the third wire in the second cavity, wherein the second wire is a cathode and the third wire is an anode.

12. The method as in claim 8,
wire bonding a third wire to either the chip or the lead frame;
wire bonding a fourth wire to either the chip or the lead frame;
wire bonding a fifth wire to either the chip or the lead frame;
depositing a polymer gel on the second and third wires to form a first mandrel connected to the second and third wires;
depositing the polymer gel on the fourth and fifth wires to form a second mandrel connected to the fourth and fifth wires;
encapsulating the lead frame, chip, the first mandrel, and the second mandrel with an epoxy molding compound;
removing a first portion of the epoxy molding compound to expose the first mandrel;
removing a second portion of the epoxy molding compound to expose the second mandrel removing a portion of the first mandrel to form a first cavity in the epoxy molding compound with the second and third wires in the first cavity;
removing a portion of the second mandrel to form a second cavity in the epoxy molding compound with the fourth and fifth wires in the second cavity;
depositing a first sensor material in the first cavity;
depositing a second sensor material in the second cavity;
annealing the first sensor material, whereby a first sensor is formed; and
annealing the second sensor material, whereby a second sensor is formed.

13. The method as in claim 8, wherein depositing a sensor material comprises three-dimensional printing the sensor material.

14. The method as in claim 8, wherein annealing the first sensor material comprises laser heating the first sensor material.

15. The method as in claim 8, comprising applying a porous ceramic layer over the sensor.

16. A semiconductor sensor package manufactured by a method comprising:
providing a lead frame;
attaching a chip to the lead frame;
wire bonding a first wire to the chip and the lead frame;
wire bonding a second wire to either the chip or the lead frame;
wire bonding a third wire to either the chip or the lead frame; and
depositing a sensor material on the second and third wires, whereby a sensor is formed.

17. The semiconductor sensor package manufactured by the method as in claim 16, comprising:
depositing a polymer gel on the second and third wires to form a mandrel connected to the second and third wires;
encapsulating the lead frame, chip, and mandrel with an epoxy molding compound;
removing a portion of the epoxy molding compound to expose the mandrel;
removing a portion of the mandrel to form a cavity in the epoxy molding compound with the second and third wires in the cavity, wherein depositing a sensor material on the second and third wires comprises depositing the sensor material in the cavity; and
annealing the sensor material, whereby a sensor is formed.

18. The semiconductor sensor package manufactured by the method as in claim 16, wherein depositing a sensor material comprises three-dimensional printing the sensor material wherein annealing the sensor material comprises laser heating the sensor material.

19. The semiconductor sensor package manufactured by the method as in claim 16, wherein the sensor material forms a doped metal oxide sensor to sense a gas selected from: oxygen (O₂), nitrogen (N₂), hydrogen (H₂), carbon dioxide (CO₂), carbon monoxide (CO), hydrocarbon gas, methane (CH₄), nitric oxide (NO), nitrous oxide (N₂O), refrigerant gas (R32 and R454b), water vapor (H₂O), fluorinated gas, sulfur dioxide (SO₂), and ammonia (NH₃).

20. The semiconductor sensor package manufactured by the method as in claim 16, comprising applying a porous ceramic layer over the sensor.
